(19) United States
(12) Patent Application Publication
(10) Pub. No.: US 2024/0088065 A1
(43) Pub. Date: Mar. 14, 2024

(54) FERROELECTRIC MEMORY DEVICE ERASURE

(71) Applicant: International Business Machines Corporation, Armonk, NY (US)

(72) Inventors: Nanbo Gong, White Plains, NY (US); Takashi Ando, Eastchester, NY (US); Guy M. Cohen, Westchester, NY (US)

(21) Appl. No.: 17/940,623

(22) Filed: Sep. 8, 2022

(51) Int. Cl. H01L 23/00; H01L 23/34; H01L 27/11507; H01L 27/1159

(52) U.S. Cl. CPC H01L 23/573; H01L 23/345; H01L 27/11507; H01L 27/1159

(57) ABSTRACT

A non-volatile memory (NVM) structure is provided including a proximity heater or a localized heater that is configured to generate Joule heating to increase temperature of a ferroelectric material layer of a ferroelectric memory device higher than a Currie temperature of the ferroelectric material layer. The Joule heating is trigged when tampering in the NVM structure is detected and as a result of the Joule heating memory erasure can occur.

### BACKGROUND

The present application relates to ferroelectric memory devices, and more particularly to erasing memory from a ferroelectric memory device using a heater.

A ferroelectric memory device is considered as a promising technology for electronic memory storage. In a ferroelectric memory device, the information is based on polarization in the ferroelectric layer, which is switchable based on the electric field, and will be non-ferroelectric once the temperature of the ferroelectric layer is above the Curie temperature. A ferroelectric memory device is a non-volatile type of memory, and thus stored data could be stolen by physical unauthorized access to the memory. Such unauthorized access can jeopardize the security of the data by extracting cryptographic keys from the memory.

### SUMMARY

A non-volatile memory (NVM) structure is provided including a proximity heater or a localized heater that is configured to generate Joule heating to increase temperature of a ferroelectric material layer of a ferroelectric memory device higher than a Currie temperature of the ferroelectric material layer. The Joule heating is trigged when tampering in the NVM structure is detected and as a result of the Joule heating memory erasure can occur.

In one aspect of the present application, a NVM structure including a proximity heater is provided. In one embodiment, the NVM structure includes at least one ferroelectric memory device including a ferroelectric material layer, and a proximity heater located adjacent to the at least one ferroelectric memory device. When triggered, the proximity heater is configured to generate Joule heating to increase temperature of the ferroelectric material layer higher than a Currie temperature of the ferroelectric material layer.

In some embodiments of the present application, the proximity heater is spaced apart from the at least one ferroelectric memory device and is embedded in a dielectric material layer that is thermally conductive and electrically insulating. Examples of such dielectric material layers include AlN, BN, or diamond-like carbon.

In some embodiments of the present application, the at least one ferroelectric memory device is a ferroelectric field effect transistor (FeFET) including a source region, a drain region, and a gate electrode. In such embodiments, the gate electrode of the FeFET is located on top of the ferroelectric material layer.

In some embodiments of the present application, the at least one ferroelectric memory device is a one-transistor one-capacitor ferroelectric random access memory (1T1C FeRAM). In such embodiments, the ferroelectric material layer of the 1T1C FeRAM is positioned between a bottom electrode and a top electrode.

In some embodiments of the present application, the at least one ferroelectric memory device is a ferroelectric tunnel junction (FeTJ) device. In such embodiments, the ferroelectric material layer of the FeTJ device is located between a first metal layer and a second metal layer. In such embodiments, the first junction formed between the first metal layer and the ferroelectric material layer has a higher energy barrier height than the second junction formed between the second metal layer and the ferroelectric material layer In yet other embodiments, the first junction formed between the first metal layer and the ferroelectric material layer has a lower energy barrier height than the second junction formed between the second metal layer and the ferroelectric material layer.

In some embodiments of the present application, the proximity heater is located between a top electrode and a bottom electrode.

In some embodiments of the present application, the proximity heater is spaced apart from the at least one ferroelectric memory device by a distance from 1 nm to 40 nm. The distance is sufficient to facilitate the Joule heating of the ferroelectric material layer when an event triggers the need of such Joule heating.

In some embodiments of the present application, the at least one ferroelectric memory device includes a plurality of ferroelectric memory devices (i.e., FeFETs, IT1C FeRAMs, or FeTJs), each ferroelectric memory device of the plurality of ferroelectric memory devices includes the ferroelectric material layer. In such embodiments, a proximity heater is located between each of the ferroelectric memory devices.

In some embodiments of the present application, the proximity heater is wired to a processor, wherein the processor notifies the proximity heater to active when a trigger event occurs. When activated, the proximity heater causes sufficient Joule heating of the ferroelectric material layer such that memory erasure can occur. The processor can include a notification unit or a tamper detection unit.

In another embodiment, the NVM structure includes a key storage region including at least one first ferroelectric field effect transistor (FeFET), the at least one first FeFET includes a source region, a drain region, a ferroelectric material layer, and a localized heater, and wherein the localized heater in the key storage region is located on top of the ferroelectric material layer. The NVM structure of this embodiment also includes a memory region located adjacent to the key storage region, the memory region includes at least one second FeFET, the at least one second FeFET includes a source region, a drain region, a ferroelectric material layer, a U-shaped localized heater, and a gate electrode, and wherein the U-shaped localized heater in the memory region is located on a top of the ferroelectric material layer and is present along a sidewall and a bottom wall of the gate electrode of the at least one second FeFET.

In some embodiments of the present application, an interlayer dielectric (ILD) material layer is present that separates the key storage region and the memory region from each other.

In some embodiments of the present application, the U-shaped localized heater has a topmost surface that is coplanar with a topmost surface of the gate electrode present in the memory region.

In some embodiments of the present application, the localized heater in the key storage region is configured to generate Joule heating to increase temperature of the ferroelectric material layer of the at least one first FeFET higher than a Currie temperature of the ferroelectric material layer of the at least one first FeFET such that at least a private encryption key is erased. In some embodiments, the private encryption key erasure is sufficient and no data erasure is needed in the memory region.

In some embodiments of the present application, the localized heater in the memory region is also configured to generate Joule heating to increase temperature of the ferroelectric material layer of the at least one second FeFET higher than a Currie temperature of the ferroelectric material layer of the at least one second FeFET such that data is erased in the memory region. This embodiment of including data erasure in the memory region adds extra security protection to the overall system.

In some embodiments of the present application, the NVM structure further includes a first spacer and a second spacer present in the key storage region, wherein the second spacer is located along a sidewall of the localized heater of the at least one first FeFET and entirely on top of the ferroelectric material layer of the at least one first FeFET, and the first spacer is located along a sidewall of the second spacer and along a sidewall of the ferroelectric material layer of the at least one first FeFET.

In some embodiments of the present application, the NVM structure further includes a spacer in the memory region, wherein the spacer in the memory region is present along a sidewall of the U-shaped localized heater of the at least one second FeFET and a sidewall of the ferroelectric material layer of the at least one second FeFET.

In some embodiments of the present application, the localized heater of the at least one first FeFET is wired to a processor, wherein the processor notifies the localized heater of the at least one first FeFET to active when a trigger event occurs. In some embodiments, the U-shaped localized heater of the at least one second FeFET is also wired to the processor such that when the processor notifies the U-shaped localized heater that a trigger event has occurred the U-shaped localized heater activates. This embodiment adds extra security and need not be used in all instances. Thus, and some embodiments of the present application, the localized heater of the at least one second FeFET is not wired to a processor such that data is maintained in that region. The processor can include a notification unit or a tamper detection unit.

### BRIEF DESCRIPTION OF THE DRAWINGS

FIG. 1 is a cross sectional view of a first exemplary NVM structure in accordance with an embodiment of the present application, the first exemplary NVM structure including a ferroelectric memory device region that includes a FeFET and a heater located in close proximity to the FeFET that is present in the ferroelectric memory device region.

FIG. 2 is a cross sectional view of alternative ferroelectric memory device that can replace the FeFET shown in FIG. 1, in this embodiment the alternative ferroelectric memory device is a one-transistor one-capacitor ferroelectric random access memory (1T1C FeRAM), and the 1T1C FeRAM is intended to be used in FIG. 1 instead of the FeFET.

FIG. 3 is a cross sectional view of a yet another alternative ferroelectric memory device that can replace the FeFET shown in FIG. 1, in this embodiment the alternative ferroelectric memory device is a ferroelectric tunnel junction device, and the ferroelectric tunnel junction device is intended to be used in FIG. 1 instead of the FeFET.

FIG. 4 is a cross sectional view of a second exemplary NVM structure in accordance with another embodiment of the present application, the second exemplary structure including a key storage region and an adjacent memory region, both regions including a FeFET having a built-in (i.e., localized) heater.

FIG. 5A is a top down view of the exemplary NVM structure shown in FIG. 4 showing that the localized heater in the key memory region is surrounded by a second spacer.

FIG. 5B is a top down view of the exemplary NVM structure shown in FIG. 4 showing that the localized heater in the memory region surrounds a gate electrode.

FIG. 6 is a diagram showing a memory erasure system for use with the second exemplary structure as is shown in FIG. 4.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

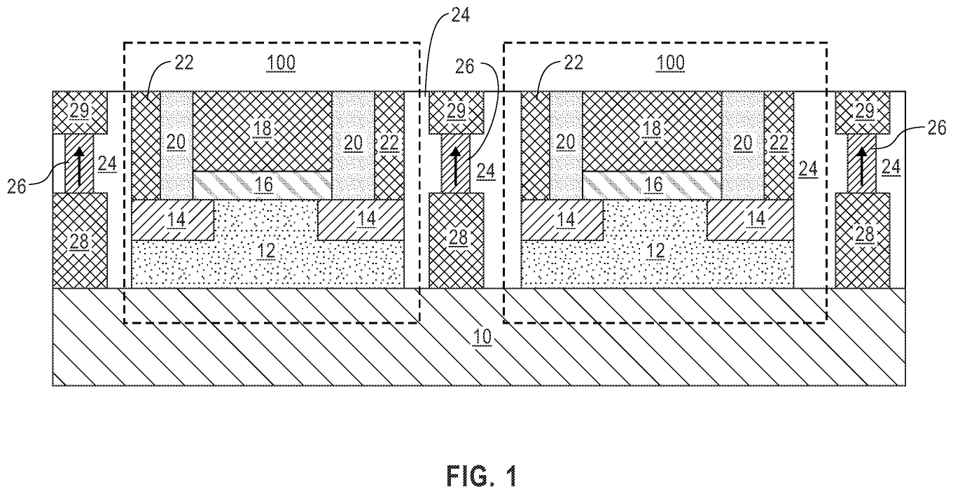

Referring first to FIG. 1, there is illustrated a first exemplary NVM structure in accordance with an embodiment of the present application, the first exemplary NVM structure includes a ferroelectric memory device region 100 that includes a FeFET as a ferroelectric memory device, and a heater 26 located in close proximity to the ferroelectric memory device that is present in the ferroelectric memory device region 100. In this embodiment, heater 26 can be referred to a proximity heater since it located adjacent to the ferroelectric memory device region 100. By way of one example, two ferroelectric memory device regions 100 each including a ferroelectric memory device (e.g. a FeFET as exemplified in FIG. 1) are described and illustrated. Although two ferroelectric memory device regions 100 are described and illustrated, the present application contemplates a structure having a single ferroelectric memory device region 100, or having more than two ferroelectric memory device regions 100. Each ferroelectric memory device region 100 includes a ferroelectric memory device.

In FIG. 1, the ferroelectric memory device is a FeFET that includes a source region (e.g., one of the source/rain regions 14 depicted in the far left FeFET shown in FIG. 1), a drain region (e.g., another of the source/drain regions 14 depicted in the far left FeFET shown in FIG. 1), a ferroelectric material layer 16, and a gate electrode 18. In some embodiments, a thin interfacial layer (IL) can be included between the ferroelectric material layer 16 and the top surface of the FET's channel that is located within semiconductor material layer 12. For silicon-based FETs, the IL can be composed of silicon dioxide (SiO₂). In FIG. 1, the gate electrode 18 is located on top of the ferroelectric material layer 16. Within the ferroelectric memory device region 100, a source/drain contact structure 22 is present on the source/drain region 14, and a spacer 20 is present along a sidewall of both the gate electrode 18 and the ferroelectric material layer 16. In this embodiment, the spacer 20 is also located on the source/drain region 14 and is present between the source/drain contact structure 22 and a material stack composed of the gate electrode 18 and the ferroelectric material layer 16. As is shown in FIG. 1, the source/drain regions 14 are located in a semiconductor material layer 12 that is located above a substrate 10. The semiconductor material layer 12 includes a channel of the FeFET that runs from one of the source/drain regions 14 of the FeFET to the another of the source/drain regions 14 of the FeFET; a channel region is located beneath each ferroelectric material layer 16 shown in FIG. 1.

In some embodiments, the substrate 10 can include a semiconductor material that has semiconducting properties. Examples of semiconductor materials that can be used to provide the substrate 10 include, but are not limited to, silicon (Si), a silicon germanium (SiGe) alloy, a silicon germanium carbide (SiGeC) alloy, germanium (Ge), III/V compound semiconductors or II/VI compound semiconductors. In some embodiments (not shown), the substrate 10 is a semiconductor-on-insulator SOI) substrate that includes a buried dielectric material layer such as a buried silicon oxide layer and/or a buried boron nitride layer separating a first semiconductor substrate material layer from a second semiconductor substrate material layer. In other embodiments, the substrate 10 is a bulk semiconductor substrate that is entirely composed of at least one of semiconductor materials as mentioned above. In other embodiments, substrate 10 can be composed of a material that provides mechanical support and/or thermal conductance to the active device layer (which includes the ferroelectric memory and the interconnects). Examples of such materials include, but are not limited to, glass, sapphire (Al₂O₃), or mica.

The semiconductor material layer 12 which includes the channel region can be composed of one of the semiconductor materials mentioned above for substrate 10. In some embodiments, the semiconductor material layer 12 represents a processed uppermost semiconductor material layer of substrate 10.

Each source/drain region 14 is composed of a semiconductor material and a dopant. As used herein, a “source/drain or S/D” region can be a source region or a drain region depending on subsequent wiring and application of voltages during operation of the ferroelectric memory device. As is known, source/drain regions 14 are located on each side of a gate structure that includes ferroelectric material layer 14 and gate electrode 18. The semiconductor material that provides the source/drain region 14 can include one of the semiconductor materials mentioned above for the substrate 10. The semiconductor material that provides the source/drain regions 14 can be compositionally the same as, or compositionally different from, the semiconductor material that provides the semiconductor material layer 12. The dopant that is present in the source/drain regions 14 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, the source/drain regions 14 can have a dopant concentration of from 4×10²⁰ atoms/cm³ to 3×10²¹ atoms/cm³. The source/drain regions 14 can be formed by introducing a dopant into the semiconductor material layer 12 by ion implantation or, alternatively, by first forming source/drain trenches in the semiconductor material layer 12 and thereafter filling the source/drain trenches with a semiconductor material. The filling of the source/drain trenches includes an epitaxial growth process with or without dopants being present during the epitaxial growth. When dopants are not present during the epitaxial growth process, the dopant can be added to the epitaxially grown semiconductor material by ion implantation or any other suitable dopant introduction technique.

The ferroelectric material layer 16 is composed of a material (i.e., a ferroelectric material) that exhibits ferroelectricity. Ferroelectricity is the ability of the material to have a spontaneous electric polarization. This polarization can be reversed by the application of an external electrical field in the opposite direction. All ferroelectric materials exhibit a piezoelectric effect. One example of a ferroelectric material that can be employed as the ferroelectric material layer 16 is Hf₍ₓ₎Zr₍₁₋ₓ₎O₂, (HZO) where 0<x<1. In one example, the HZO ferroelectric material that is used is a composition of Hf_{0.5}Zr_{0.5}O₂. Other examples of ferroelectric materials that can be employed as the ferroelectric material layer 16 include, but are not limited to, BaTaO₂, Ba₂Bi₄Ti₅O₁₅, Pb₂Bi₄Ti₅O₁₅, BaBi₄Ti₄O₁₅, SrBi₂Ta₂O₃, BaTiO₃, PbZrO₃, PbTiO₃, Bi₁₋ₓNdₓTi₃O₁₂, Bi₄Ti₃O₁₂, or Bi₁₋ₓLaₓTi₃O₁₂. The ferroelectric material layer 16 is formed by deposition of a layer of the ferroelectric material. Deposition includes, but is not limited to, chemical vapor deposition (CVD), plasma enhanced chemical vapor deposition (PECVD), atomic layer deposition (ALD), physical vapor deposition (PVD) or sputtering. The ferroelectric material layer 16 typically has a thickness from 1 nm to 20 nm; however other thicknesses are contemplated and can be used as the thickness of the ferroelectric material layer 16.

The gate electrode 18 can include an electrically conductive metal-containing material including, but not limited to tungsten (W), titanium (Ti), tantalum (Ta), ruthenium (Ru), zirconium (Zr), cobalt (Co), copper (Cu), aluminum (Al), lead (Pb), platinum (Pt), tin (Sn), silver (Ag), or gold (Au), tantalum nitride (TaN), titanium nitride (TiN), tantalum carbide (TaCx), titanium carbide (TiC), titanium aluminum carbide, tungsten silicide (WSi₂), tungsten nitride (WN), ruthenium oxide (RuO₂), cobalt silicide, or nickel silicide. In some embodiments, a work function metal (WFM) layer can be employed as either the electrically conductive metal-containing material that provides the gate electrode or as a separate layer that is located between the ferroelectric material layer and the gate electrode. The WFM layer can be used to set a threshold voltage of the FeFET to a desired value. In some embodiments, the WFM layer can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the WFM layer can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof.

The spacer 20 includes any dielectric spacer material such as, silicon oxide, silicon nitride, SiBCN, SiOCN or SiOC. The spacer 20 can be formed by deposition followed by a spacer etch.

The source/drain contact structure 22 is composed of at least a contact conductor material such as, for example, W, Cu, Al, Co, Ru, Mo, Os, Ir, Rh, or an alloy thereof. The contact conductor material can be formed by any suitable deposition method such as, for example, CVD, PVD, atomic layer deposition (ALD) or plating. The source/drain contact structure 22 can include one or more contact liners (not shown) formed along sidewalls of contact openings used in forming the source/drain contact structure 22. In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material. Exemplary diffusion barrier materials include, but are not limited to, Ru, TiN, TaN, WN, WC, an alloy thereof, or a stack thereof such as Ti/TiN and Ti/WC. In either embodiment, the contact liner can be formed utilizing a conformal deposition process including PVD, CVD or ALD. The contact liner that is formed can have a thickness ranging from 1 nm to 8 nm, although lesser and greater thicknesses can also be employed.

The proximity heater 26 is composed of any resistive material such as, for example, TiN, TaN, carbon, hydrogen-doped carbon, or combinations thereof such as a stack of TiN/TaN/TiN. The resistive material that provides the proximity heater 26 can be formed by a deposition process such as, for example, CVD, PECVD, ALD, PVD, sputtering or platting. In the present application, the proximity heater 26 can be located to the left and right of the ferroelectric memory device region 100 as is shown in FIG. 1 as well as being located in and out of the plane of the drawing sheet including FIG. 1. The proximity heater 26 is spaced apart from the ferroelectric memory device that is within the ferroelectric device region 100 by a distance from 1 nm to 40 nm, with a distance from 1 nm to 10 nm being more typical in some embodiments. The distances provided herein are sufficient to facilitate Joule heating of the ferroelectric material layer 16 when an event triggers the need of such Joule heating. Joule heating is employed to increase a temperature of the ferroelectric material layer 16 higher than a Currie temperature of the ferroelectric material layer. Above the Curie temperature the ferroelectric memory layer 16 loses its memory ability and thus provides a means for erasing memory of ferroelectric memory device. Not all ferroelectric memory devices within an array (or a plurality) of ferroelectric memory devices need have their data erased. Instead, only those ferroelectric memory devices in which a trigger event is detected can have their data erased therefrom. As will be explained below, dielectric material layer 24 may be selected to be a good thermal conductor (while being a good electrical insulator). Due to the better thermal coupling such material will allow a more efficient heating even at larger distances between the proximity heater 26 and the ferroelectric material layer 16.

A trigger event can be used to activate memory erasure. A trigger event can be any occurrence which results in the activation of a certain protocol. In the present application, a trigger event refers to a threshold which may be met to activate a memory erasure. Trigger events can include, for example, reaching the end of a subscription (e.g., the threshold is a date), receiving a manual instruction to delete (e.g., the threshold is a set input value), identifying a tampering attempt (e.g., the threshold is recognition of attempted unauthorized access), or other similar occurrences. Expiration triggers can be tied to external systems (e.g., a remote subscription calendar), internal systems (e.g., dates and/or times entered into a calendar on a local device), or some combination thereof. Tampering attempts can be identified by a number of means including, for example, the removal of a memory module from a rack without providing a proper access code, an attempted bypass of a device enclosure, or other recognition of unauthorized tampering with a device.

Tampering can involve reverse engineering the contents of a memory selection, such as reverse engineering the contents of an encryption key. Many physical reverse engineering techniques require accessing the chip structures through imaging (e.g., electron beams from scanning electron microscopy, focused ion beam, x-ray, et cetera) and therefore generate radiation (e.g., photocurrent, laser beam induced current, electron beam induced current, et cetera). Some embodiments of the present application can exploit this principle by using photovoltaic cells to convert the radiation from a tampering attempt into a current which triggers the tamper response (e.g., powers the heater activation) to erase the data.

Tampering can involve unauthorized physical access (e.g., unsanctioned removal of a computer board from a computer or opening a box containing a computer chip). Tampering can include unauthorized access of a secure room. In some embodiments, sensors may detect an intrusion with sensors; such sensors may include, for example, sensors for light, temperature, humidity, pressure, similar detectors, or some combination thereof.

Tampering can include electrical probing and delayering for extracting secret keys to inducing faults (e.g. flipping states) to force a device to conduct unauthorized operations. An unauthorized access attempt typically deploys a range of techniques to locate specific circuits and structures; these techniques usually involve radiation for imaging or inducing currents and faults. Again, some embodiments of the present application can reroute the energy from the radiation or currents to activate an anti-tamper device and erase the targeted memory and/or the memory containing the encryption key for the targeted memory. For example, a photovoltaic cell may automatically capture and reroute energy from a tampering attempt to power the activation of the proximity heater 26.

As is illustrated in FIG. 1, the proximity heater 26 is spaced apart from the at least one ferroelectric memory device within the ferroelectric memory device region 100 and is embedded in a dielectric material layer 24 that is thermally conductive and electrically insulating. Examples of such materials that can be used as dielectric material layer 24 include, but are not limited to, aluminum nitride (AlN), boron nitride (BN) or diamond-like carbon. Dielectric material layer 24 can be formed by a deposition process including, for example, CVD, PECVD, or ALD.

As is illustrated in FIG. 1, the proximity heater 26 is positioned between a bottom electrode 28 and a top electrode 29. The bottom electrode 28 and the top electrode 29 are composed of any electrode material such as, for example, Ta, TaN, Ti, TiN, Ru, RuN, RuTa, RuTaN, Co, CoWP, CoN, Cu, W, WN or any combination thereof. The electrode material that provides the bottom and top electrodes 28, 29 can be deposited by CVD, PECVD, ALD, sputtering or plating. In FIG. 1, the arrows show the direction of current flow which is from bottom electrode 28 through proximity heater 26 and into the top electrode 28. In some embodiments of the present application, the circuitry that connects to the proximity heater 26 can be electrically decoupled from the circuitry that connects to ferroelectric memory device region 100. This provides additional layer of security preventing activation of proximity heater 26 by exploiting the circuitry in the ferroelectric memory device region 100.

The FeFET illustrated in the ferroelectric memory device region 100 can be formed utilizing any well-known FeFET forming technique. After forming the FeFET, dielectric material layer 24 is formed laterally adjacent to the FeFET and thereafter the dielectric material layer 24 can be processed to include the bottom electrode 28, the proximity heater 26 and the top electrode 29. These elements/components are formed by forming various trenches/openings in the dielectric material layer 24 and then filling the various trenches/openings with the appropriate material to provide the bottom electrode 28, the proximity heater 26 and the top electrode 29 in the dielectric material layer 26.

In embodiments of the present application (which will become more apparent by the discussion herein below), the proximity heater 26 is wired to a processor which can include a notification unit, a tamper detection unit or other devices which can activate the proximity heater 26 (or the localized heater 26L and/or 26R in the embodiment shown in FIG. 4). The processor can also activate the heaters as a result of a trigger event. In the present application, the processor is wired to the heaters such that when a trigger event has been detected the heaters can be activated to raise the temperature of the ferroelectric memory layer 16 above the Curie temperature such that data erasure can occur. It is important to note that the above-mentioned processor is not the CPU which is read and write to the memory module. The CPU is completely decoupled from the circuitry that operates the proximity heater. This guarantee that a malicious code that may execute on the CPU cannot be used to erase the memory. The tampering detection unit is therefore electrically decoupled from the CPU circuitry.

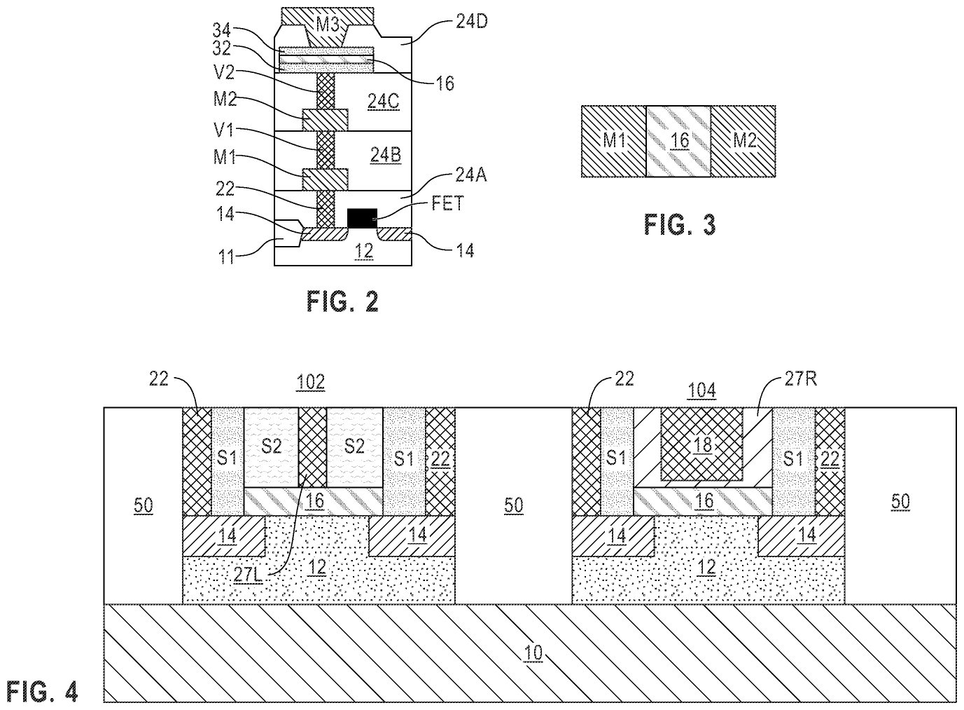

Reference is now made to FIG. 2, which illustrate an alternative ferroelectric memory device that can used instead of the FeFET shown in FIG. 1. Notably, the ferroelectric memory device shown in FIG. 2 can be inserted into the ferroelectric memory device region 100 and used instead of the FeFET shown in FIG. 1; the proximity heater 26 of FIG. 1 would in such embodiments now be located laterally adjacent to the ferroelectric memory device shown in FIG. 2. In this embodiment, the alternative ferroelectric memory device is a 1T1C FeRAM. The 1T1C FeRAM includes one FET that includes a gate dielectric material layer and a gate electrode layer; the gate dielectric material layer and the gate electrode layer are not separately shown in FIG. 2. The FET is located above a semiconductor material layer 12. A source/drain region 14 is located at the footprint of the FET and or each side of the FET, and an isolation structure 11 is located in the semiconductor material layer 12. The 1T1C FeRAM further includes capacitor 32/16/34 which includes bottom electrode 33, ferroelectric material layer 16, and top electrode 34. As is shown, the 1T1C FeRAM further includes source/drain contact structure 22 embedded in a first dielectric material layer 24A; the FET is also embedded in this first dielectric material layer 24A. The 1T1C FeRAM further includes a second dielectric material layer 24B having a first metal line, M1, and a first metal via, V1 embedded therein, a third dielectric material layer 24C having a second metal line, M2, and second metal via, V2, embedded therein, a fourth dielectric material layer 24D that embeds the capacitor 32/26/34, and a third metal line, M3, that contacts the top electrode 34 of the capacitor 32/16/34.

The first semiconductor material layer 12, source/drain regions 14, the gate electrode material, the source/drain contact structure 22 and ferroelectric material layer 16 that are used in providing the 1T1C FeRAM are the same as those mentioned above in providing the FeFET shown in FIG. 1. The first dielectric material layer 24A, the second dielectric material layer 24B, the third dielectric material layer 24C and the fourth dielectric material layer 24D of the 1T1C FeRAM include one of the dielectric materials mentioned above for dielectric material layer 24. The bottom electrode 32 and the top electrode 24 of the capacitor include one of the electrode materials mentioned above for forming the bottom electrode 28 and top electrode 29 in FIG. 1. In embodiments, the proximity heaters 26 (and bottom and top electrodes 28. 29) can be formed in the dielectric material stack composed of the first, second, third and fourth dielectric material layers and a separate dielectric material layer 24 need not be used.

The gate dielectric material layer of the FET is composed of a gate dielectric material such as, for example silicon oxide, or a dielectric material having a dielectric constant greater than 4.0 (such dielectric materials can be referred to as a high-k gate dielectric material). All dielectric constants mentioned herein are measured in a vacuum unless otherwise stated. Illustrative examples of high-k gate dielectric materials include metal oxides such as, for example, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The high-k gate dielectric material can further include dopants such as lanthanum (La), aluminum (Al) and/or magnesium (Mg).

The isolation structure 11 can be a trench isolation structure that is composed of a trench dielectric material such as, for example, silicon oxide. Alternatively, the isolation structure 11 can be a thermal isolation structure that is formed utilizing a thermal oxidation process. The isolation structure 11 can have a topmost surface that is located below, coplanar with, or located above, a topmost surface of the semiconductor material layer 12.

Each of the first, second and third metal lines, M1, M2, M3, and each of the first and second metal vias V1 and V2 are composed of an electrically conductive interconnect metal or electrically conductive interconnect metal alloy. Examples of electrically conductive interconnect metals include, but are not limited to, Cu, Al, Co, or W, while examples of electrically conductive interconnect metal alloys include, but are not limited to, a Cu—Al alloy.

The 1TIC FeFRAM shown in FIG. 2 can be formed utilizing any well known 1T1C FeRAM processing technique. For example, the FET can be formed on the semiconductor material layer 12, thereafter isolation structure 11 and the source/drain regions 14 are formed utilizing techniques well known in the art. After forming the FET, the various dielectric material layers within the embedded wiring are formed utilizing conventional interconnect wiring forming processes. The capacitor is formed on third dielectric material layer 24C prior to forming the fourth dielectric material layer 24D. The proximity heater 26 (and bottom and top electrodes 28, 29) can be formed into any one of the dielectric material layers of the 1T1C FeRAM.

Referring now to FIG. 3, there is illustrated yet another alternative ferroelectric memory device that can instead of the FeFET shown in FIG. 1. Notably, the ferroelectric memory device shown in FIG. 3 can be inserted into the ferroelectric memory device region 100 and used instead of the FeFET; the proximity heater 26 of FIG. 1 would in such embodiments now be located laterally adjacent to the ferroelectric memory device shown in FIG. 3. In this embodiment the alternative ferroelectric memory device is a ferroelectric tunnel junction, or FeTJ device. In this embodiment, the ferroelectric material layer 16 of the FeTJ device is located between a first metal layer M1 and a second metal layer M1. In this embodiment, M1 can be, for example, Pt, Co, Ti, TiN, Ta, TaN, W, PtO, Jr or IrO, while M2 can be, for example, Pt, Co, Ti, TiN, Ta, TaN, W, PtO, Jr or IrO or a semiconductor material. In such embodiments, the first junction formed between the first metal layer M1 and the ferroelectric material layer 16 has a higher energy barrier height than the second junction formed between the second metal layer M2 and the ferroelectric material layer 16. In yet other embodiments, the first junction formed between the first metal layer M1 and the ferroelectric material layer 16 has a lower energy barrier height than the second junction formed between the second metal layer M2 and the ferroelectric material layer 16. The FeTJ device shown in FIG. 3 can be formed utilizing techniques that are well known to those skilled in the art.

Referring is now made to FIG. 4, there is illustrated a second exemplary NVM structure in accordance with another embodiment of the present application. The second exemplary NVM structure includes a key storage region 102 and an adjacent memory region 104, both regions including a FeFET having a built-in heater (or localized 27L, 27R). Notably, and within the key storage region 102 there is present at least one first FeFET that is present on a semiconductor material layer 12. The at least one first FeFET includes a source region (one of the source/drain regions 14 in the key memory device region 102), a drain region (another of the source/drain regions 14 shown in the key memory device region 102), a ferroelectric material layer 16, and a localized heater 27L. In this embodiment, the localized heater 27L in the key storage region 102 is located entirely on top of the ferroelectric material layer 16. The localized heater 27L in the key storage region 102 is configured to generate Joule heating to increase temperature of the ferroelectric material layer 16 of the at least one first FeFET higher than a Currie temperature of the ferroelectric material layer 16 of the at least one first FeFET such that at least a private encryption key is erased.

The first FeFET further includes a first spacer S1, a second spacer S2 and source/drain contact structure 22. As is shown in FIG. 4, the second spacer S2 is located along a sidewall of the localized heater 27L of the at least one first FeFET and is present on top of the ferroelectric material layer 16 of the at least one first FeFET, and the first spacer S1 is located along a sidewall of the second spacer S2 and along a sidewall of the ferroelectric material layer 16 of the at least one first FeFET. The first spacer Si lands on a portion of the source/drain region 14. As is further shown, the source/drain contact structure 22 is located laterally adjacent to, and along a sidewall of the first spacer Si; the source/drain contact structure 22 lands on another portion of the source/drain region 14. In this embodiment, each of the source/drain contact structure 22, the first spacer Si, the second spacer S2 and the localized heater 27L has a topmost surface that is coplanar with each other and coplanar with a topmost surface of an ILD material layer 50.

In the memory region 104 that is located adjacent to the key storage region 102, there is present at least one second FeFET which is located on semiconductor material layer 12; the semiconductor material layer 12 in both the key storage region 102 and the memory region 104 are located on substrate 10. The at least one second FeFET includes a source region (one of the source/drain regions 14 in the memory region 104), a drain region (another of the source/drain regions 14 present in the memory region 104), a ferroelectric material layer 16, a U-shaped localized heater 27R, and a gate electrode 18. In this embodiment, the U-shaped localized heater 27R in the memory region 104 is located on a top of the ferroelectric material layer 16 and is present along a sidewall and a bottom wall of the gate electrode 18 of the at least one second FeFET. In this embodiment, the U-shaped localized heater 27R has a topmost surface that is coplanar with a topmost surface of the gate electrode 18 present in the memory region 104. The U-shaped localized heater 27R in the memory region 104 is configured to generate Joule heating to increase temperature of the ferroelectric material layer 16 of the at least one second FeFET higher than a Currie temperature of the ferroelectric material layer 16 of the at least one second FeFET such that data is erased in the memory region 104. In some embodiments, the U-shaped localized heater 27R is unconnected to any processor and thus the data in the memory region 104 can be maintained. In a preferred embodiment there is no need to erase the data in the memory region 104, since it is enough to just erase the encryption key that is present in the key storage region 102. For a very secure system there may be a requirement to erase both the memories in the key storage region 102 and the memory region 104. In that case the U-shaped heater 27R is wired to a processor such that it can raise the temperature in the ferroelectric memory layer 16 that is present in the memory region 104 above the Curie temperature.

The second FeFET further includes spacer (i.e., a first spacer Si). The spacer (i.e., first spacer S1) in the memory region 104 is present along a sidewall of the U-shaped localized heater 27R of the at least one second FeFET and a sidewall of the ferroelectric material layer 16 of the at least one second FeFET.

In this embodiment, the substrate 10, the semiconductor material layer 12, the source/drain regions 14, the ferroelectric material layer 16, the gate electrode 18 and source/drain contact structure 22 include materials as mentioned above for the same components/elements used in providing the mentioned above in the FeFET shown in FIG. 1. The localized heaters 27L and 27R include one of the materials mentioned above for proximity heater 26. The first and second spacers include one of the spacer dielectric materials mentioned spacer 20.

ILD material layer 50 incudes a dielectric material such as, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. The ILD material layer 40 can be formed by deposition, followed by a planarization process.

The exemplary NVM structure can be formed by first forming in any order the first FeFET and second FeFET utilizing techniques that are well known to those skilled in the art. The ILD material layer 50 is then formed as described above.

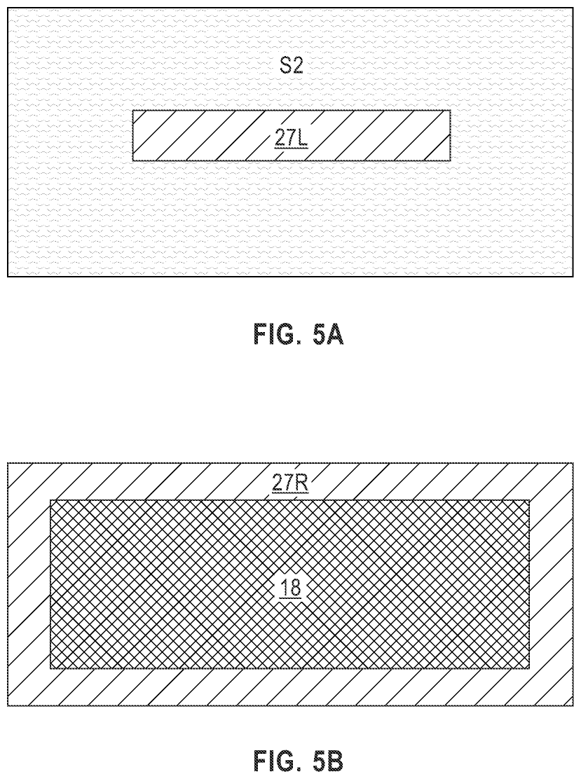

Referring to FIG. 5A, there is provided a top down view of the exemplary NVM structure shown in FIG. 4 showing that the localized heater 27L in the key memory region 102 is surrounded by second spacer, S2, while FIG. 5B is a top down view of the exemplary NVM structure shown in FIG. 4 showing that the localized heater 27R in the memory region 104 surrounds gate electrode 18. Note that the coplanar first spacer S1, source/drain contact structure 22 and the ILD material layer 50 are not shown for clarity.

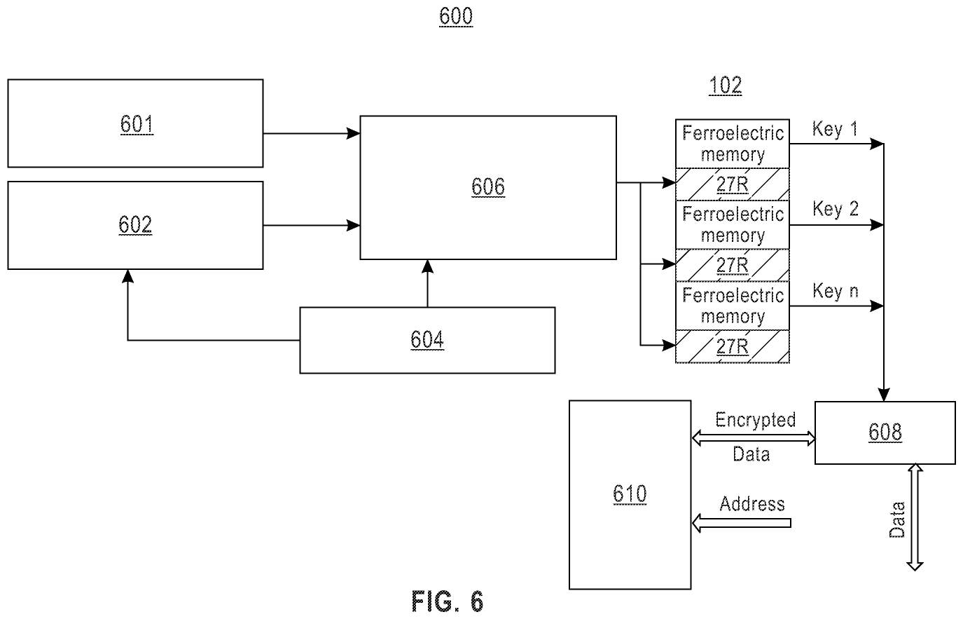

Reference is now made to FIG. 6 which illustrates a memory system 600 with erasure capabilities in accordance with embodiments of the present application and that can be used with the exemplary NVM structure shown in FIG. 4. The memory system 600 can include one or more package integrity sensors 602 and one or more environmental sensors 601. Package integrity sensors 602 may be able to detect physical tampering with a device such as by, for example, identifying an attempt to bypass a device enclosure. Environmental sensors 601 may be able to detect changes to the environment of the device, for example, removal of a device from a memory rack by detecting a change in velocity, rotational motion, stability, ambient temperature, and/or ambient humidity. In some embodiments, an authorization code may be used to identify authorized access, such as authorized maintenance which may require a device enclosure bypass and/or removal from a certain environment.

An emergency power source 604 may provide energy to package integrity sensors 602 and/or environmental sensors 601. The emergency power source 604 may also provide power, either directly or indirectly, to a tampering detector 606 (i.e., a processor). The tampering detector 606 may be, for example, a notification device (e.g., relaying an input command), a tampering detection unit (e.g., an anti-tamper device), a unit for identifying certain events (e.g., subscription expiration), a combination thereof, or any other unit which may be used to identify trigger events. The tampering detector 606 may be in communication with the package integrity sensors 602 and the environmental sensors 601 such that the tampering detector 606 receives information from the package integrity sensors 602 and the environmental sensors 601.

Some embodiments of the present application include an anti-tamper device for detecting physical tampering as well as for providing a tamper response by erasure of data. Erasure of the memory cluster within the key storage region 102 erases any data, including encryption keys (i.e., Key 1 and/or Key 2 and/or Key N), stored within the memory cluster that is present in the key storage region 102. Erasing an encryption key stored within the memory cluster in the key storage region 102 prevents encryption module 608 from decrypting the data using the encryption keys. In some embodiments, such a memory cluster in the storage key region 102 may be implemented using ferroelectric memory devices (such as, first FeFET shown in FIG. 4) and localized heaters 27R as discussed in reference to FIG. 4; for example, the processor (i.e., the tampering detector 606) may activate at least one of the localized heaters 27L embedded in the ferroelectric memory devices to erase the data contained in a memory cluster in the key storage region 102. The processor can also be used to heat the U-shaped localized heaters 27R in the memory region 104 (this is not depicted in FIG. 6, but can be readily achieved by wiring the tampering detector 606 (or other like processor) to the U-shaped Localized heaters 27R).

In some embodiments (not shown), a proximity heater 26 used with the ferroelectric memory device shown in FIG. 1, 2 or 3 may abut a thermally coupling material that may be thermally conductive to facilitate efficient heat energy transfer from the proximity heaters to such ferroelectric memory devices. In such an embodiment, the thermally coupling material may be electronically insulating to prevent electronic pulses being passed between the proximity heaters and the ferroelectric memory device shown in FIG. 1, 2 or 3.

Referring back to FIG. 6, the ferroelectric memories may be in contact with the encryption module 608. The ferroelectric memories may act as an encryption key for the encryption module 608. For example, the may store the encryption keys for the encryption module 608. For example, data written to the storage memory 610 may be encrypted as it is written to the storage memory 610. Similarly, encrypted data read from the storage memory 610 may be decrypted while it is fetched from memory. In such an embodiment, both encryption and decryption may be based on one or more encryption keys stored in the ferroelectric memories.

The encryption module 608 may be in communication with a memory storage module 610. The storage memory 610 may be any type of memory (e.g., PCM, dynamic random access memory (DRAM), flash, et cetera) or any combination thereof. In embodiments, the memory region 104 can be used as the storage memory 610. The encryption module 608 may also be in communication with a data source. The encryption module 608 may, for example, receive data from the data source, encrypt the data, and store the encrypted data in the storage memory 610.

The memory system in accordance with the present application may be accessible only locally (e.g., physical access on-site), only virtually (e.g., by way of a local area connection or internet connection), or some combination thereof. In some embodiments, a local-only connection may be preferred to prevent any virtual access as it may enable unauthorized remote access. In some embodiments, a virtual connection maybe preferred to enable remote access such as, for example, via a specifically authorized remote machine which may communicate with the memory system 600 via end-to-end encryption to enable the triggering of erasure of the memory system 600 based on a non-local event.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A non-volatile memory (NVM) structure comprising:
at least one ferroelectric memory device comprising a ferroelectric material layer; and
a proximity heater located adjacent to the at least one ferroelectric memory device, wherein the proximity heater is configured to generate Joule heating to increase temperature of the ferroelectric material layer higher than a Currie temperature of the ferroelectric material layer.

2. The NVM structure of claim 1, wherein the proximity heater is spaced apart from the at least one ferroelectric memory device and is embedded in a dielectric material layer that is thermally conductive and electrically insulating.

3. The NVM structure of claim 1, wherein the at least one ferroelectric memory device is a ferroelectric field effect transistor (FeFET) comprising a source region, a drain region, and a gate electrode, and wherein the gate electrode is located on top of the ferroelectric material layer.

4. The NVM structure of claim 1, wherein the at least one ferroelectric memory device is a one-transistor one-capacitor ferroelectric random access memory (1T1C FeRAM), wherein the ferroelectric material layer is positioned between a first electrode and a second electrode.

5. The NVM structure of claim 1, wherein the at least one ferroelectric memory device is ferroelectric tunnel junction device, wherein the ferroelectric material layer is located between a first metal layer and a second metal layer.

6. The NVM structure of claim 1, wherein the proximity heater is located between a bottom electrode and a top electrode.

7. The NVM structure of claim 1, wherein the proximity heater is spaced apart from the at least one ferroelectric memory device by a distance from 1 nm to 40 nm.

8. The NVM structure of claim 1, wherein the at least one ferroelectric memory device comprises a plurality of ferroelectric memory devices, each ferroelectric memory device of the plurality of ferroelectric memory devices comprise at least the ferroelectric material layer.

9. The NVM structure of claim 1, wherein the proximity heater is wired to a processor, wherein the processor notifies the proximity heater to active when a trigger event occurs.

10. The NVM structure of claim 9, wherein the processor comprises a notification unit or a tamper detection unit.

11. A non-volatile memory (NVM) structure comprising:
a key storage region comprising at least one first ferroelectric field effect transistor (FeFET), the at least one first FeFET comprises a source region, a drain region, a ferroelectric material layer, and a localized heater, and wherein the localized heater in the key storage region is located on top of the ferroelectric material layer; and
a memory region located adjacent to the key storage region, the memory region comprising at least one second FeFET, the at least one second FeFET comprising a source region, a drain region, a ferroelectric material layer, a U-shaped localized heater, and a gate electrode, and wherein the U-shaped localized heater in the memory region is located on a top of the ferroelectric material layer and is present along a sidewall and a bottom wall of the gate electrode of the at least one second FeFET.

12. The NVM structure of claim 11, further comprising an interlayer dielectric material (ILD) layer separating the key storage region and the memory region.

13. The NVM structure of claim 11, wherein the U-shaped localized heater has a topmost surface that is coplanar with a topmost surface of the gate electrode present in the memory region.

14. The NVM structure of claim 11, wherein the localized heater in the key storage region is configured to generate Joule heating to increase temperature of the ferroelectric material layer of the at least one first FeFET higher than a Currie temperature of the ferroelectric material layer of the at least one first FeFET such that at least a private encryption key is erased.

15. The NVM structure of claim 14, wherein the localized heater in the memory region is configured to generate Joule heating to increase temperature of the ferroelectric material layer of the at least one second FeFET higher than a Currie temperature of the ferroelectric material layer of the at least one second FeFET such that data is erased in the memory region.

16. The NVM structure of claim 11, further comprising a first spacer and a second spacer present in the key storage region, wherein the second spacer is located along a sidewall of the localized heater of the at least one first FeFET and entirely on top of the ferroelectric material layer of the at least one first FeFET, and the first spacer is located along a sidewall of the second spacer and along a sidewall of the ferroelectric material layer of the at least one first FeFET.

17. The NVM structure of claim 11, further comprising a spacer in the memory region, wherein the spacer in the memory region is present along a sidewall of the U-shaped localized heater of the at least one second FeFET and a sidewall of the ferroelectric material layer of the at least one second FeFET.

18. The NVM structure of claim 11, wherein the localized heater of the at least one first FeFET is wired to a processor, wherein the processor notifies the localized heater of the at least one first FeFET to active when a trigger event occurs.

19. The NVM structure of claim 18, wherein the U-shaped localized heater of the at least one second FeFET is wired to the processor, wherein the processor also notifies the U-shaped localized heater of the at least one second FeFET to active when the trigger event occurs.

20. The NVM structure of claim 18, wherein the processor comprises at a notification unit or a tamper detection unit.
